(19) United States
(12) Patent Application Publication
(10) Pub. No.: US 2026/0362863 A1
(43) Pub. Date: Nov. 12, 2026

(54) SPECULAR REFLECTOR PERIMETER ARRANGEMENTS FOR LIGHT-EMITTING DIODE DEVICES

(71) Applicant: CreeLED, Inc., Durham, NC (US)

(72) Inventors: Colin Blakely, Raleigh, NC (US); David Suich, Durham, NC (US); Scott Wegner, Boulder, CO (US)

(21) Appl. No.: 19/201,222

(22) Filed: May 7, 2025

(51) Int. Cl. H10H 20/851; H10H 20/85

(52) U.S. Cl. CPC H10H 20/8515; H10H 20/8502; H10H 20/8506; H10H 20/8508

(57) ABSTRACT

Light-emitting diode (LED) devices and, more particularly, specular reflector perimeter arrangements for LED devices are disclosed. In an embodiment, an LED component is provided that includes an LED chip comprising a top face and a bottom face, wherein a bottom face of the LED chip is mounted to a support element, and wherein the LED chip further comprises an active LED structure and a transparent substrate, wherein the transparent substrate is between the top face and the active LED structure. The LED component also includes a lumiphoric layer over the top face and a perimeter sidewall around the LED chip, wherein an internal surface of the perimeter sidewall facing the LED chip is a specular reflector.

### FIELD OF THE DISCLOSURE

The present disclosure relates to light-emitting diode (LED) devices, and more particularly specular reflector perimeter arrangements for LED devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

LED packages that have LED chips that are flip-chips can have color over angle differences where depending on the angle that the LED chip is observed, the intensity of different colors can vary due to the geometry of the LED chip and where the light is emitted from within the LED chip. For example, the offset geometry of the blue emission layer changes over angle due to the different ratios of lumiphoric material to blue emission layer depending on the angle, such that the flux emission becomes increasingly more yellow at greater angles. This is detrimental to the color uniformity of LED chips and other applications as the color is observed to change with viewing angle.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to specular reflector perimeter arrangements for LED devices. A sidewall of the perimeter arrangement can be a specular reflector so that the LED device has improved color over angle, especially at high viewing or measurement angles. When the perimeter sidewalls are white or are otherwise diffuse reflectors, the light reflected off the perimeter sidewalls from the active LED structure of the LED device is reflected in all directions so that the reflected light has a lesser luminosity than the light that arrives directly from the active LED structure. Accordingly, for a flip-chip LED device with a lumiphoric layer, when viewing the sidewall, the blue luminance is lesser on the sidewall, so there is proportionally less blue light transmitted through the lumiphore and proportionally more yellow light than there is when looking at the center of the LED device. Therefore, at high viewing angles, the overall color of the LED device is proportionally more yellow than when viewed at low viewing angles. In an embodiment with a specular reflector sidewall, the light from the blue emission layer of the LED chip reflects off the perimeter sidewall keeping the same luminosity as light arriving directly from the active LED structure, so that it high angles the light emitted by the LED device is more similar to light emitted at low angles.

In an embodiment, an LED component is provided that includes an LED chip comprising a top face and a bottom face, wherein the bottom face of the LED chip is mounted to a substrate, and wherein the LED chip further comprises an active LED structure and a transparent substrate, wherein the transparent substrate is between the top face and the active LED structure. The LED component also includes a lumiphoric layer over the top layer and a perimeter sidewall around the LED chip, wherein an internal surface of the perimeter sidewall facing the LED chip is a specular reflector.

In an embodiment, the internal surface of the perimeter sidewall is curved with a concave curvature with respect to the LED chip.

In an embodiment, the concave curvature is such that at any viewing angle of the internal surface of the perimeter sidewall from above the LED component, the specular reflector reflects the active LED structure of the LED chip.

In an embodiment, an axis of curvature of the internal surface of the perimeter sidewall intersects the active LED structure of the LED chip.

In an embodiment, the LED chip is a flip-chip.

In an embodiment, the LED component further includes a cover structure over the LED chip, wherein the lumiphoric layer is on the cover structure.

In an embodiment, the cover structure is sapphire.

In an embodiment, there is a transparent filler material between a sidewall of the LED chip and the internal surface of the perimeter sidewall.

In an embodiment, there is an air gap between a sidewall of the LED chip and the internal surface of the perimeter sidewall.

In an embodiment, an LED component includes a flip-chip LED chip comprising a top face and a bottom face, wherein the bottom face of the LED chip is mounted to a substrate, and wherein the LED chip further comprises an active LED structure and a transparent substrate, wherein the transparent substrate is between the top face and the active LED structure. The LED component also includes a lumiphoric layer over the top layer and a perimeter sidewall around the LED chip, wherein an internal surface of the perimeter sidewall facing the LED chip is curved and is a specular reflector.

In an embodiment, a curvature of the internal surface of the perimeter sidewall is concave with respect to the LED chip.

In an embodiment, the curvature is such that at any viewing angle of the internal surface of the perimeter sidewall from above the LED component, the specular reflector reflects the active LED structure of the LED chip.

In an embodiment, an axis of curvature of the internal surface of the perimeter sidewall intersects the active LED structure of the LED chip.

In an embodiment, the LED component also includes a cover structure over the LED chip, wherein the lumiphoric layer is on the cover structure.

In an embodiment, the cover structure is sapphire.

In an embodiment, the transparent substrate comprises silicone.

In an embodiment, there is a transparent filler material between a sidewall of the LED chip and the internal surface of the perimeter sidewall.

In an embodiment, there is an air gap between a sidewall of the LED chip and the internal surface of the perimeter sidewall.

In an embodiment, an LED component includes an LED chip comprising a top face and a bottom face, wherein the bottom face of the LED chip is mounted to a substrate, and wherein the LED chip further comprises an active LED structure and a transparent substrate, wherein the transparent substrate is between the top face and the active LED structure. The LED component also includes a cover structure over the LED chip, a lumiphoric layer on the cover structure, and a perimeter sidewall around the LED chip, wherein an internal surface of the perimeter sidewall facing the LED chip has a concave curvature and is a specular reflector.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of a light-emitting diode (LED) device with a specular reflector perimeter arrangement and lumiphoric layer according to aspects disclosed herein.

FIG. 1B is a top-down view of the LED device of FIG. 1A according to aspects disclosed herein.

FIG. 2 is a cross-sectional view of an LED device with a specular reflector perimeter arrangement with a cover structure and lumiphoric layer according to aspects disclosed herein.

FIG. 3 is a cross-sectional view of an LED device similar to FIG. 2 with a filler material according to aspects disclosed herein.

FIG. 4 is a cross-sectional view of the LED device of FIG. 1A, showing the curvature of the perimeter sidewall according to aspects disclosed herein.

FIG. 5 is a cross-sectional view of the LED device of FIG. 1A, showing light rays according to aspects disclosed herein.

FIG. 6 is a perspective view of an LED device with a perimeter arrangement that has a diffuse reflector sidewall according to aspects disclosed herein.

FIG. 7 is a perspective view of an LED device with a perimeter arrangement that has a specular reflector sidewall according to aspects disclosed herein.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to specular reflector perimeter arrangements for LED devices. A sidewall of the perimeter arrangement can be a specular reflector so that the LED device has improved color over angle, especially at high viewing or measurement angles. When the perimeter sidewalls are white or are otherwise diffuse reflectors, the light reflected off the perimeter sidewalls from the active LED structure of the LED device is reflected in all directions so that the reflected light has a lesser luminosity than the light that arrives directly from the active LED structure. Accordingly, for a flip-chip LED device with a lumiphoric layer, when viewing the sidewall, the blue luminance is lesser on the sidewall, so there is proportionally less blue light transmitted through the lumiphore and proportionally more yellow light than there is when looking at the center of the LED device. Therefore, at high viewing angles, the overall color of the LED device is proportionally more yellow than when viewed at low viewing angles. In an embodiment with a specular reflector sidewall, the light from the blue emission layer of the LED chip reflects off the perimeter sidewall keeping the same luminosity as light arriving directly from the active LED structure, so that it high angles the light emitted by the LED device is more similar to light emitted at low angles.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a lateral geometry. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure or a submount structure.

Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, polyamide, polyimide, polyethylene terephthalate, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. Encapsulant materials may also form lenses that direct light in desired emission directions and/or patterns. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

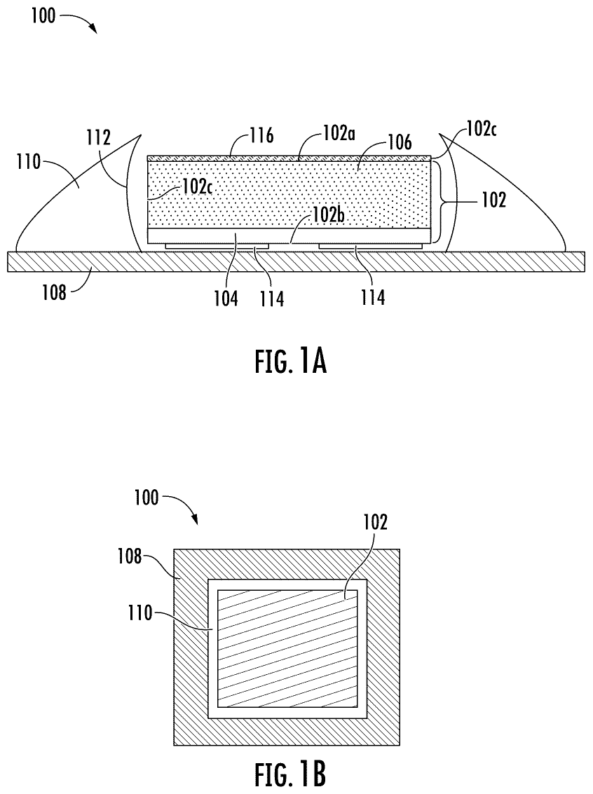

FIG. 1A is a cross-sectional view of an LED device 100 with a specular reflector perimeter arrangement and lumiphoric layer according to aspects disclosed herein.

In FIG. 1A, the LED device 100 includes a flip-chip LED chip 102 that is mounted on a surface such as a support element 108, which may embody a lead frame structure or a submount such as a printed circuit board (PCB), where electrodes 114 of the LED chip 102 are electrically connected to traces on the support element 108.

The LED chip 102 has a bottom face 102b and a top face 102a, and comprises an active LED structure 104 from which the light is emitted from the LED chip, and a transparent substrate 106 through which the light emitted by the active LED structure 104 can pass through. Typically, the light emitted by the LED chip 102 is a first peak wavelength such as blue, and so in various embodiments, a lumiphoric layer 116 comprising one or more phosphors is provided to convert the generally blue light to a light that appears white. In various embodiments, the first peak wavelength may be other colors. While much of the light that is emitted by the active LED structure 104 passes through the transparent substrate 106 and then the lumiphoric layer 116, some of the light emitted by the active LED structure 104 exits sidewalls 102c of the LED chip 102 without passing through the lumiphoric layer 116. In the embodiment shown in FIG. 1A, the lumiphoric layer 116 is on the top face 102a of the LED chip 102. In other embodiment, there can be layers between the LED chip 102 and the lumiphoric layer 116. In various embodiments, the lumiphoric layer 116 may also extend at least partially down the sidewalls 102c of the LED chip 102.

In embodiments, perimeter arrangements 110 can be provided to surround the LED chip 102 and shape the emission pattern of the light so that more of the light is directed upwards from the LED chip 102 to improve the far field pattern, increase the efficiency of the LED chip 102 and also so that more of the light is directed through the lumiphoric layer 116 to improve the color over angle. The “color over angle” refers to the variation in the perceived color of light emitted from the device as the viewing angle changes. By improving the color over angle, the variation in the perceived color of light is reduced when changing the viewing angle.

In an embodiment, the perimeter arrangements 110 can be silicone or plastic, metal, or some other suitable material. The perimeter arrangement 110 can have a sidewall 112 that is curved and is a specular reflector and can be referred to as a specular reflector sidewall 112. The specular reflector can be a metal layer or could be a distributed Bragg reflector (DBR). A DBR is formed from multiple layers of alternating materials with different refractive index, or by periodic variation of some characteristic (such as height) of a dielectric waveguide, resulting in periodic variation in the effective refractive index in the guide. Each layer boundary causes a partial reflection and refraction of an optical wave. The specular reflector sidewall 112 can, in various embodiments, be curved with a concave curvature such that at any viewing angle of the specular reflector sidewall 112 from outside the LED device 100, the specular reflector sidewall 112 reflects the active LED structure 104 of the LED chip 102.

FIG. 1B shows the top-down view of the LED device 100 from FIG. 1A, where the LED chip 102 is within the perimeter arrangement 110 which surrounds the LED chip 102, and the LED chip 102 can be mounted on the support element 108. The perimeter arrangement 110 can also be mounted, placed, or formed on the support element 108.

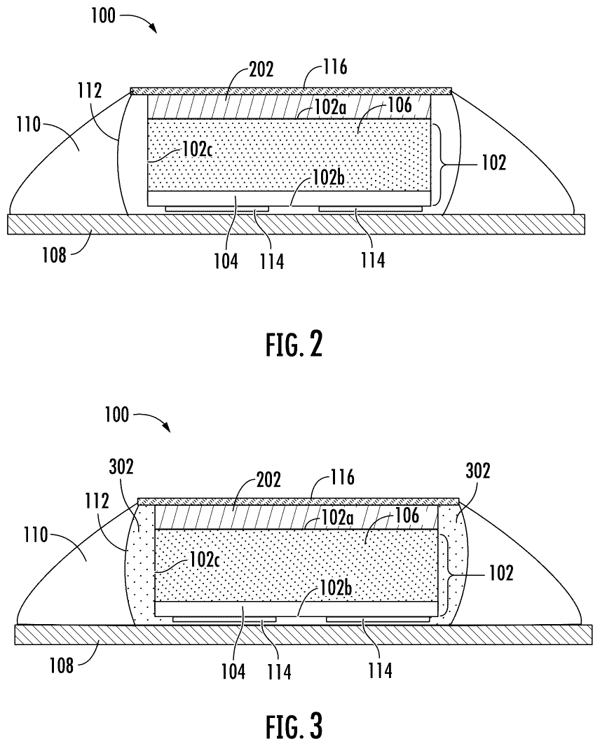

FIG. 2 is a cross-sectional view of an LED device 100 with a specular reflector perimeter arrangement with a cover structure and lumiphoric layer according to aspects disclosed herein. The LED device 100 in FIG. 2 is the same as in FIG. 1A, except that in FIG. 2, there is a cover structure 202 that is over the top face 102a of the LED chip 102. The cover structure 202 could be a lens or could just be serving as a protective cover over the LED chip 102. The cover structure 202 could be sapphire, glass, silicone, or other suitable material. In an embodiment, the lumiphoric layer 116 could be placed over the cover structure 202. In other embodiments, the lumiphoric layer 116 could be embedded within the cover structure 202.

In an embodiment, there can be an airgap between the sidewall 102c of the LED chip 102 and the perimeter arrangement 110. In other embodiments, as shown in FIG. 3, there can be a filler material 302 between the LED chip 102 and the perimeter arrangement 110. FIG. 3 is a cross-sectional view of an LED device 100 similar to FIG. 2 with the filler material 302 according to aspects disclosed herein. The filler material 302 could be silicone or other transparent medium and can provide protection to the LED chip 102 and also provide stabilization and vibration mitigation.

FIG. 4 is a cross-sectional view of the LED device 100 of FIG. 1A, showing the curvature of the specular reflector sidewall 112 according to aspects disclosed herein.

In the embodiment shown in FIG. 4, the curvature of the specular reflector sidewall 112 is ellipsoidal, with a major axis 402 that intersects the active LED structure 104 of the LED chip 102. In other embodiments, different curvatures, like parabolic, hyperbolic, and circular are possible, with major axis or axes of symmetry that may or may not intersect with the active LED structure 104.

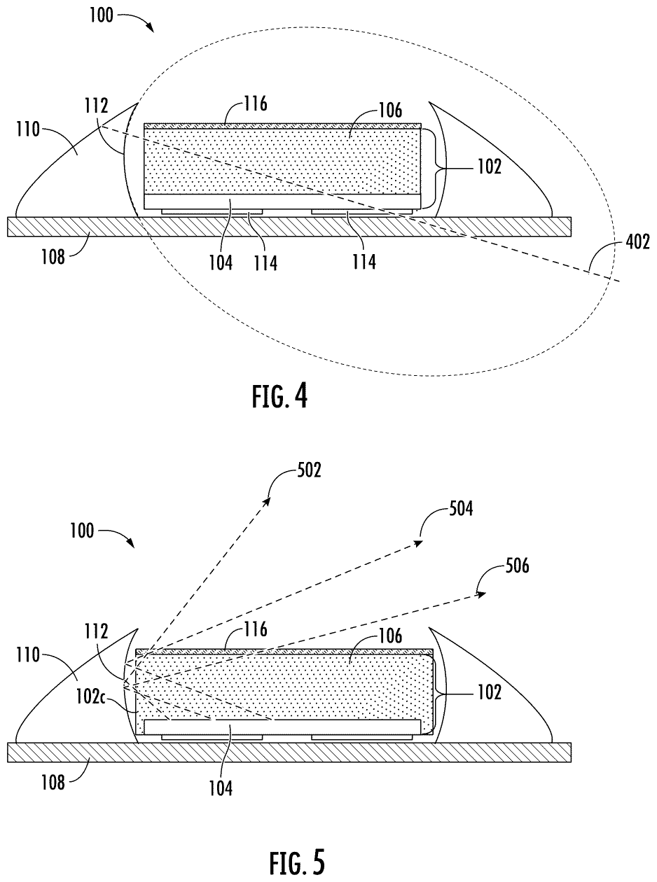

FIG. 5 is a cross-sectional view of the LED device 100 of FIG. 1A, showing light rays according to aspects disclosed herein. To visually represent the light rays, FIG. 5 depicts ray traces of various viewing angles using the embodiment shown in FIG. 1A.

For example, for ray 502, light emitted by the active LED structure 104 of the LED chip 102 exits the LED chip out of the sidewall 102c, and reflects off the specular reflector sidewall 112, passing through the lumiphoric layer 116 when exiting the LED device 100. Similar paths are shown for rays 504 and 506.

If the specular reflector sidewall 112 were white, or a just a diffuse reflector, the light reflecting off the sidewall 112 would be lesser in luminance than the light arriving directly from the active LED structure 104, so that at when viewing the sidewall, the blue luminance is lesser on the sidewall, so there is proportionally less blue light transmitted through the lumiphore and proportionally more yellow light than there is when looking at the center of the LED device. Therefore, for an observer at high viewing angles, the overall color of the LED device 100 is proportionally more yellow than when viewed at low viewing angles. This would be because at a high angle, due to the geometry of the viewing angle, the observer sees a higher ratio of the sidewall reflections than seeing light directly emitted from the active LED structure 104.

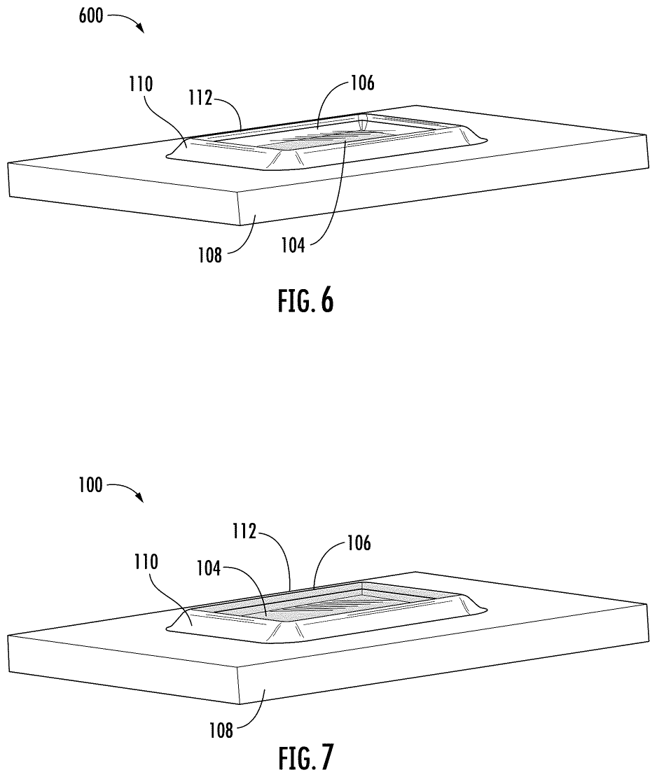

This is demonstrated for example by FIG. 6 which is a perspective view of an LED device 600 with a perimeter arrangement that has a diffuse reflector sidewall 112 according to aspects disclosed herein. By contrast, FIG. 7 is the perspective view an LED device 100 with a perimeter arrangement that has a specular reflector sidewall 112 according to aspects disclosed herein.

In FIG. 6, when looking at a high angle, more of the perimeter sidewall 112 is visible than the active LED structure 104 portion of the LED chip 102. Accordingly with a diffuse reflector or non-reflective perimeter sidewall, the light reflecting off the sidewall would be lesser in luminosity than the light arriving directly from the active LED structure 104, and thus when looking at the sidewall 112, since the proportion of blue light is lesser than the light arriving directly from the active LED structure 104, the sidewall 112 would appear yellower than the active LED structure 104 portions that are visible, and so the overall light emitted by the LED device 600 would be somewhat yellower. At a sufficiently high enough viewing angle, only the sidewall 112 is visible with no visibility to the active LED structure 104, which would lead to a much yellower color.

By contrast, in FIG. 7, since the sidewall 112 is a specular reflector, the light reflecting off the specular reflector sidewall 112 is the same color as the active LED structure 104, and so after conversion by the lumiphoric layer 116, would have a similar color profile as if the LED device 100 were viewed from straight above. This is true even for the very high viewing angles where only the sidewall 112 is viewable. Even at such a high viewing angle, because the sidewall 112 is a specular reflector, the proportion of blue light in the overall light output by the LED device 100 is similar to that when viewed at low viewing angles.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) component, comprising:
an LED chip comprising a top face and a bottom face, wherein the bottom face of the LED chip is mounted to a support element, and wherein the LED chip further comprises an active LED structure and a transparent substrate wherein the transparent substrate is between the top face and the active LED structure;
a lumiphoric layer over the top face; and
a perimeter sidewall around the LED chip, wherein an internal surface of the perimeter sidewall facing the LED chip is a specular reflector.

2. The LED component of claim 1, wherein the internal surface of the perimeter sidewall is curved with a concave curvature with respect to the LED chip.

3. The LED component of claim 2, wherein the concave curvature is such that at any viewing angle of the internal surface of the perimeter sidewall from above the LED component, the specular reflector reflects the active LED structure of the LED chip.

4. The LED component of claim 1, wherein an axis of curvature of the internal surface of the perimeter sidewall intersects the active LED structure of the LED chip.

5. The LED component of claim 1, wherein the LED chip is a flip-chip.

6. The LED component of claim 1, further comprising a cover structure over the LED chip, wherein the lumiphoric layer is on the cover structure.

7. The LED component of claim 6, wherein the cover structure is sapphire.

8. The LED component of claim 1, wherein the transparent substrate comprises silicone.

9. The LED component of claim 1, wherein there is a transparent filler material between a sidewall of the LED chip and the internal surface of the perimeter sidewall.

10. The LED component of claim 1, wherein there is an air gap between a sidewall of the LED chip and the internal surface of the perimeter sidewall.

11. A light-emitting diode (LED) component, comprising:
a flip-chip LED chip comprising a top face and a bottom face, wherein the bottom face of the LED chip is mounted to a support element, and wherein the LED chip further comprises an active LED structure and a transparent substrate, wherein the transparent substrate is between the top face and the active LED structure;
a lumiphoric layer over the top face; and
a perimeter sidewall around the LED chip, wherein an internal surface of the perimeter sidewall facing the LED chip is curved and is a specular reflector.

12. The LED component of claim 11, wherein a curvature of the internal surface of the perimeter sidewall is concave with respect to the LED chip.

13. The LED component of claim 12, wherein the curvature is such that at any viewing angle of the internal surface of the perimeter sidewall from above the LED component, the specular reflector reflects the active LED structure of the LED chip.

14. The LED component of claim 11, wherein an axis of curvature of the internal surface of the perimeter sidewall intersects the active LED structure of the LED chip.

15. The LED component of claim 11, further comprising a cover structure over the LED chip, wherein the lumiphoric layer is on the cover structure.

16. The LED component of claim 15, wherein the cover structure is sapphire.

17. The LED component of claim 11, wherein the transparent substrate comprises silicone.

18. The LED component of claim 11, wherein there is a transparent filler material between a sidewall of the LED chip and the internal surface of the perimeter sidewall.

19. The LED component of claim 11, wherein there is an air gap between a sidewall of the LED chip and the internal surface of the perimeter sidewall.

20. A light-emitting diode (LED) component, comprising:
an LED chip comprising a top face and a bottom face, wherein the bottom face of the LED chip is mounted to a support element, and wherein the LED chip further comprises an active LED structure and a transparent substrate, wherein the transparent substrate is between the top face and the active LED structure;
a cover structure over the LED chip;
a lumiphoric layer on the cover structure; and
a perimeter sidewall around the LED chip, wherein an internal surface of the perimeter sidewall facing the LED chip has a concave curvature and is a specular reflector.
